(19) United States
(12) Patent Application Publication
(10) Pub. No.: US 2006/0232254 A1
(43) Pub. Date: Oct. 19, 2006

(54) Charging unit with a transmission unit

(76) Inventor: Alexander Osswald, Stuttgart (DE)

Correspondence Address: STRIKER, STRIKER & STENBY, 103 EAST NECK ROAD, HUNTINGTON, NY, 11743, US

(21) Appl. No.: 11/395,865

(22) Filed: Mar. 31, 2006

(30) Foreign Application Priority Data
Apr. 4, 2005 (DE) 10 2005 015265.1

(51) Int. Cl. G01R 31/36; G06F 19/00; G05F 1/10; H02J 3/12

(52) U.S. Cl. 323/234; 702/63

(57) ABSTRACT

A charging-unit receiver has at least one transmission unit provided for transmitting information, and the transmission unit is configured for a teletransmission of the information.

### BACKGROUND OF THE INVENTION

The present invention is directed to a charging unit with a transmission unit, which is provided for transmitting information.

A charging unit with a transmission unit designed as a charging device is known, the charging unit being provided to transmit information to an operator regarding the state of a charging process. The transmission can take place optically, e.g., via one or more light emitting diodes or via an LCD display, and/or acoustically, e.g., via a loudspeaker.

### SUMMARY OF THE INVENTION

Accordingly, it is an object of the present invention to provide the charging unit with a transmission unit for transmitting information, which is a further improvement of the existing charging units.

In keeping with these objects and with others which will become apparent hereinafter, one feature of the present invention resides, briefly stated, in a charging unit with at least one transmission unit for transmitting information, wherein the transmission unit is provided for the teletransmission of information.

In this context, the term “provided” is intended to mean, in particular, “equipped”, “designed” and/or “programmed”. “Teletransmission” is intended to mean, in particular, transmission that can take place between the transmission unit and a unit located at a distance from the transmission unit, the transmission unit being advantageously provided for the transmission of information across a distance greater than 2 m, particularly advantageously across a distance greater than 7 m, and particularly preferably, across a distance greater than 15 m.

The capability of a transmission unit to teletransmit information provides the operator with a high level of operating comfort and a great deal of flexibility, since the operator can receive information from a charging unit that is located, e.g., far away from the operator or even out of the operator's sight and/or hearing range. The present invention is particularly suited for use in an industrial setting, e.g., in a manufacturing hall, where an operator can receive information from the charging unit located, e.g., in a charging station situated far away from where the operator is, e.g., on a manufacturing line.

The transmission unit is advantageously provided to transmit information wirelessly, at least to a certain extent. As a result, operating comfort, in particular the mobility of an operator, can be increased further, since the use of a cable connection between the charging unit and a unit located where the operator is can be eliminated. Transmission can also take place via a cable connection, e.g., a USB connection, a telephone line and/or a network cable. Using this cable connection, safety-relevant information, e.g., the temperature of the charging unit, can be advantageously transmitted, by way of which safety can be increased, e.g., if the wireless transmission malfunctions.

In a further embodiment of the present invention, the transmission unit is a radio transmission unit. “Radio transmission unit” is intended to mean a transmission unit which is provided for transmitting electromagnetic waves, e.g., radio waves, microwaves and/or infrared radiation, in particular. As a result, large ranges of transmission can be advantageously realized using simple design means. In addition, cost-effective standard components can be used to build the radio transmission unit.

The transmission unit is preferably an optical and/or acoustic teletransmission unit. In this context, optical and/or acoustic teletransmission is intended to mean optical and/or acoustic transmission across long distances, and “long distances” are intended to mean, in particular, distances greater than 5 m, advantageously greater than 10 m, and, particularly preferably, greater than 15 m. For this purpose, the optical teletransmission unit advantageously has a surface size greater than 20 cm², particularly advantageously greater than 40 cm², and particularly preferably, greater than 60 cm², and/or it is provided to emit radiation via a circumferential side, whereby a “circumferential side” is intended to mean, in particular, a side that abuts a bottom side and/or a top side. Acoustic teletransmission can take place via a loudspeaker that transmits an acoustic signal and/or voice output. As a result of this embodiment of the present invention, information can be communicated directly from the charging unit to the operator, who is located far away, and advantageously in an optical and/or acoustic manner.

To obtain an advantageous angle of radiation—preferably greater than 2π steradians—with an optical teletransmission unit, the optical teletransmission unit preferably extends beyond a top side of the charging unit. Furthermore, various information can be easily transmitted, e.g., via a flashing, an intensity and/or color change, etc., of a light source of the optical teletransmission unit.

Advantageously, the optical and/or acoustic teletransmission unit is equipped with a setting unit, via which an operator can adjust a volume, voice output, signal melody, intensity and/or color tailored specifically to various basic conditions and/or certain information.

It is also provided that the charging unit include a memory unit for storing identification information, the transmission unit being provided for the transmission of identification information. As a result, the charging unit can identified, e.g., by a remote receiving unit. This is particularly advantageous when a plurality of charging units is used simultaneously, e.g., in an industrial setting, since an operator can use the identification information to associate part of the information received by a charging unit with a certain charging unit. Furthermore, the memory unit could be provided to allow a user to specifically store information, e.g., identification information, in particular. As a result, an address which is easily understood by the operator can be assigned to the charging unit.

The transmission unit is preferably provided to supply information to a data network. As a result, information transmitted by the transmission unit can be advantageously processed further within a data network, e.g., within the Internet, a WLAN network, and/or a local intranet. Existing devices, e.g., WLAN routers or computers, etc., can be advantageously used for this purpose.

It is also provided that the transmission unit be provided to supply information to a mobile radiocommunications network. For this purpose, the transmission unit is preferably equipped to transmit microwaves in a GSM standard frequency range, e.g., a frequency range between 400 MHz and 2 GHz, in particular. As a result, an operator can advantageously receive the information via a mobile telephone system, e.g., in the form of a text message and/or a multimedia message. Existing devices, such as mobile radio telephones in particular, can be advantageously used, and the use of additional devices can be avoided.

The charging unit preferably includes a receiving unit. As a result, advantageous communication between an operator and the charging unit can be attained. The operator is provided with a great deal of flexibility of use in that he can, e.g., query or control the charging unit, e.g., by transmitting information to the receiving unit.

The charging unit is advantageously designed as a charging device. In this embodiment of the present invention, e.g., a plurality of rechargeable batteries can be charged in the charging unit, the transmission unit being used to transmit information to the rechargeable batteries. In addition, an increase in the weight of the rechargeable battery can be prevented. Furthermore, a power supply device integrated in the charging unit designed as a charging device can be advantageously utilized. As an alternative and/or in addition thereto, it is also feasible, however, for the charging unit according to the present invention to be a rechargeable battery, and/or for a rechargeable battery to be equipped with a transmission unit, according to the present invention, for the teletransmission of information.

In an advantageous refinement of the present invention, the transmission unit is provided for the transmission of charging-process information. Charging problems can be detected and eliminated easily and in a timely manner. “Charging-process information” is intended to mean, in particular, information about a state of charge, a charging time, etc. As an alternative and/or in addition thereto, other information that also appears reasonable to one skilled in the art can be transmitted, such as information about temperature, humidity, defects, etc.

A charging-unit receiver for a charging unit is also provided, the charging-unit receiver including a receiving unit which is provided for receiving information transmitted by the transmission unit. As a result, effective communication between the charging unit and an operator can be advantageously attained by the fact that the charging-unit receiver is designed specifically for use as a receiver for this charging unit.

The charging-unit receiver is preferably designed as a portable unit. As a result, the charging-unit receiver can be advantageously carried by an operator, which provides the operator with a particularly great deal of flexibility and even more convenience. This is suited for use in an industrial setting, in particular, e.g., in a manufacturing hall, where an operator repeatedly moves between various stations.

In a further embodiment, the charging-unit receiver includes an interface, which is provided for establishing a connection with a data network. This provides the advantage that information received by the receiving unit can be made available and processed further particularly easily in a data network, e.g., the Internet or an intranet.

The charging-unit receiver preferably includes a signaling device for the optical, acoustic and/or tactile transmission of information. The advantage of acoustic and/or tactile transmission is that an operator can be notified easily and immediately, e.g., via an acoustic signal, voice output and/or vibration, that information has been transmitted. Information can be communicated to the operator in a particularly easy manner with a high density of information via optical transmission, e.g., an LCD display, and, particularly preferably, via the transmission of visual images.

The charging-unit receiver preferably includes a transmission device, which is provided for the transmission of information to the charging unit. As a result, effective communication between an operator and a charging unit can be advantageously attained.

It is also provided that the charging-unit receiver include an input device, which is provided to allow an operator to input information. As a result, an operator can adjust a volume, voice output, signal melody, or an optical and/or tactile output of information by the charging-unit receiver tailored specifically to various basic conditions and/or preferences. In addition, the operator can assign, e.g., one or more certain charging units to the charging-unit receiver and/or query one of the associated charging units, e.g., about the state of charge of a charging process.

A system with a charging unit and a charging-unit receiver for the charging unit is also provided. As a result, a high level of compatibility between the charging unit and the charging-unit receiver can be advantageously attained by coordinating the components used to build the charging unit and the charging-unit receiver.

The novel features which are considered as characteristic for the present invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF THE DRAWINGS

FIG. 1 Shows a charging unit designed as a charging device, a USB connection, a mobile telephone, a WLAN receiver, and a network connection, in a perspective view, and

FIG. 2 Shows a charging unit designed as a rechargeable battery, in a perspective view.

### DESCRIPTION OF THE PREFERRED EMBODIMENTS

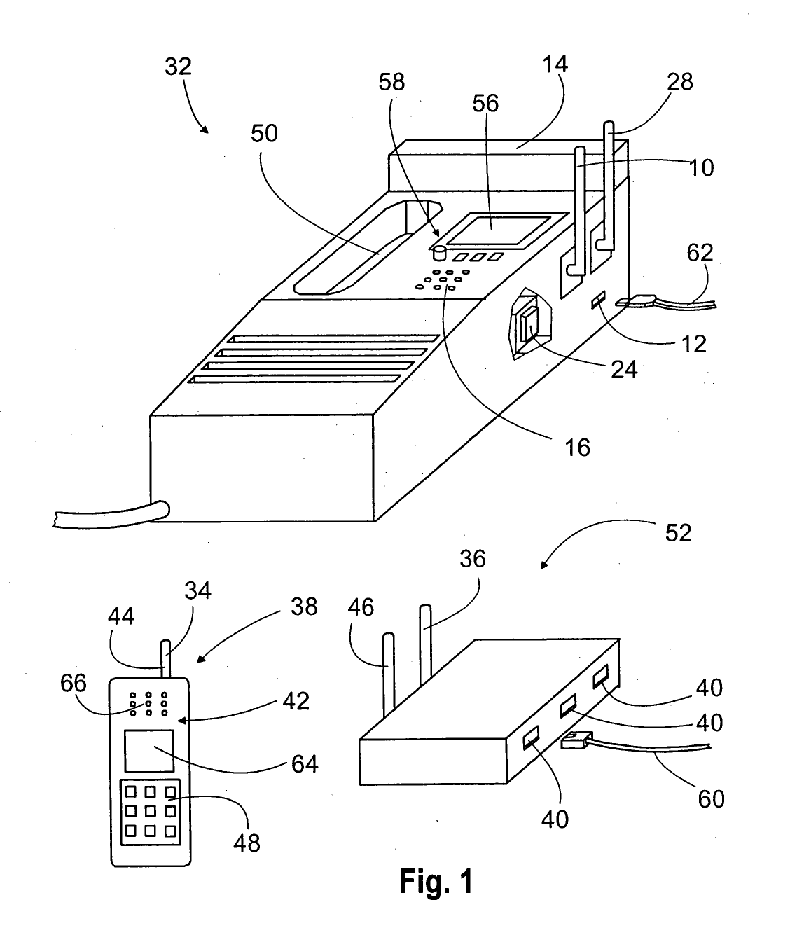

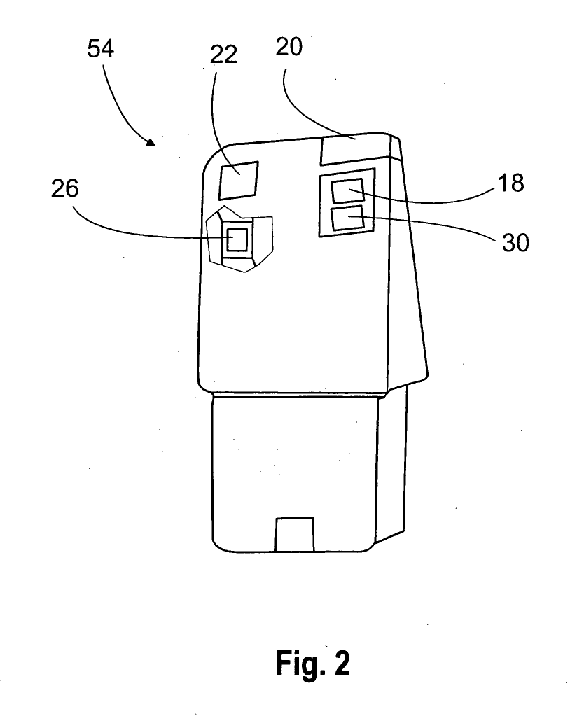

FIG. 1 shows a charging unit, designed as a charging device 32, with a rechargeable-battery receptacle 50, into which a rechargeable battery 54 shown in FIG. 2 can be plugged.

Charging device 32 in FIG. 1 has four transmission units 10, 12, 14, 16, and rechargeable battery 54 in FIG. 2 has three transmission units 18, 20 and 22. Transmission units 10, 12, 14, 16 and transmission units 18, 20, 22 are provided to transmit information to an operator who is located at a distance away from charging device 32 and/or rechargeable battery 54. This information involves, in particular, a charging process of rechargeable battery 54 or a further rechargeable battery which is plugged into charging device 32. The operator can be informed about a state of charge, a charging time, the end of the charging process, a defect in rechargeable battery 54, a temperature, etc.

The information can be transmitted to the operator—who is located at a distance away—via transmission unit 12 designed as a USB interface and/or transmission units 10 and/or 18 designed as radio transmission units, even when charging device 32 and/or rechargeable battery 54 are located out of the operator's sight and/or hearing range.

The wireless transmission of information—which is convenient for the operator—can take place via transmission using transmission unit 10 and/or 18 designed as a radio transmission unit, i.e., by transmitting the information to a unit located where the operator is, e.g., to a portable unit 38 designed as a mobile telephone.

Furthermore, an operator can receive information from charging device 32 and/or rechargeable battery 54, which are located within the operator's sight and/or hearing range, via transmission unit 14 and/or 20 designed as an optical remote transmission unit, and/or in an acoustic manner via transmission unit 16 and/or 22 designed as an acoustic teletransmission unit.

Transmission unit 14 and/or 20 includes a light source, which is not shown in FIG. 1 or 2, the light source being provided to emit a light signal via the outside surface of transmission unit 14 and/or 20. Due to the fact that transmission unit 14 is positioned such that it extends out of charging device 32, good visibility and advantageous teletransmission of the light signal can be achieved. Visibility is advantageously enhanced by the fact that a light signal emitted from transmission unit 14 can be emitted via four circumferential sides, and a light signal emitted from transmission unit 20 can be emitted via three circumferential sides. Certain events that occur in a charging process of charging device 32 or rechargeable battery 54 can be characterized by a flashing, a certain intensity and/or a certain emitted color of the light signal, thereby enabling it to be recognized quickly by the operator.

Via transmission unit 16 designed as an acoustic teletransmission unit, the operator can be alerted to information in an acoustic manner, e.g., via an acoustic signal, a melody, and/or voice output, etc., and information can also be transmitted in this manner. Using setting unit 58, the operator can set a volume that is appropriate for the surroundings, or select a desired language and/or acoustic signals or melodies that refer to certain events in the charging process.

A further optical transmission of information from charging device 32 is possible via LCD display 56, which can transmit information in the form of a text message or images.

In addition, charging device 32 and/or rechargeable battery 54 can be identified by a remote operator via the transmission of identification information stored in a memory unit 24 and/or 26 by transmission units 10 and/or 12 and 18.

Via transmission units 10, 12 on charging device 32 and/or transmission unit 18 on rechargeable battery 54, the information can be supplied to a data network, e.g., an intranet or the Internet, which is not shown in the figures. This can take place via transmission of the information by transmission unit 10 and/or 18, which is designed as a radio transmission unit, to a WLAN receiver 52. WLAN receiver 52 can receive the information via a receiving unit 36 and supply it to the data network via interfaces 40. For this purpose, WLAN receiver 52 can be connected to the data network via a network connection 60, which is plugged into interface 40. Information can also be supplied to the data network via transmission unit 12 designed as a USB interface by the fact that the information is transmitted to a computer connected to the data network via a USB connection 62 which is plugged into transmission unit 12. For example, an operator, e.g., of a further computer which is connected to the data network, can be alerted to the information, e.g., safety-relevant information in particular.

Transmission units 10 and/or 18 are also provided to supply information to a mobile radiocommunications network. Via the mobile radiocommunications network, the information can be transmitted to a mobile telephone and, in particular, to a portable unit 38 designed as a mobile telephone. For this purpose, transmission units 10 and/or 18 are provided for transmitting electromagnetic waves within the GSM standard frequency range. The information can be received by the operator in this manner, e.g., in the form of a text and/or multimedia message.

Portable unit 38 designed as a mobile telephone is designed specifically for use as a receiver for a charging device, e.g., charging device 32, or for a rechargeable battery, e.g., rechargeable battery 54, in that it includes a receiving unit 34 which is provided for receiving information transmitted from a radio transmission unit, e.g., transmission unit 10 and/or 18 designed as a radio transmission unit. Portable unit 38 is also equipped with a special program, which is provided specifically for processing charging-process information that originates in a charging device or a rechargeable battery. This program can distinguish this charging-process information from alternative information that originates in the radiocommunications network, in particular information that originates in a further mobile telephone, and specifically alert the operator to the charging-process information by transmitting a certain acoustic signal and/or a certain melody. In addition, the information can be output in a format associated with the specific circumstances. In this context, it is also feasible that the operator be informed directly via voice output about the source and/or contents of the information that was received.

Both charging device 32 and rechargeable battery 54 also include a receiving unit 28 and/or 30, while portable unit 38 and WLAN receiver 52 each include a transmission device 44 and/or 46, thereby enabling advantageous communication between the units to be attained.

Furthermore, portable unit 38 has a signalling device 42—which includes an LCD display 64 and a loudspeaker 66—which is provided for transmitting charging-process information to the operator in an optical manner, e.g., by displaying a text and/or multimedia message on LCD display 64, and/or in an acoustic manner, e.g., by transmitting an acoustic signal, a melody and/or voice output, etc., via loudspeaker 66.

Portable unit 38 also includes an input device 48, by way of which an operator can configure portable unit 38. For example, the operator can enter a certain volume for an acoustic signal, a certain melody, and/or language according to his preference. The use of input device 48 in combination with transmission device 44 is particularly advantageous because query and/or control information entered by the operator can be transmitted, e.g., to charging device 32 or rechargeable battery 54.

It will be understood that each of the elements described above, or two or more together, may also find a useful application in other types of constructions differing from the types described above.

While the invention has been illustrated and described as embodied in a charging unit with a transmission unit, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims.

1. A charging-unit receiver, comprising at least one transmission unit provided for transmitting information, said transmission unit being configured for a teletransmission of the information.

2. A charging-unit receiver as defined in claim 1, wherein said transmission unit is configured so as to transmit information wirelessly, at least to a certain extent.

3. A charging-unit receiver as defined in claim 1, wherein said transmission unit has a radio transmission unit.

4. A charging-unit receiver as defined in claim 1, wherein said transmission unit is a transmission unit selected from the group consisting of an optical teletransmission unit, an acoustic teletransmission unit, and both.

5. A charging-unit receiver as defined in claim 1; and further comprising a memory unit for storing identification information, said transmission unit being configured for transmission of the identification information.

6. A charging-unit receiver as defined in claim 1, wherein said transmission unit is configured to supply information to a data network.

7. A charging-unit receiver as defined in claim 6, wherein said transmission unit is provided to supply information to a data network formed as a mobile radio communications network.

8. A charging-unit receiver as defined in claim 1; and further comprising a receiver unit.

9. A charging-unit receiver as defined in claim 1, wherein the charging unit is configured as a charging device.

10. A charging-unit receiver for a charging unit as defined in claim 1; and further comprising a receiving unit configured for receiving information transmitted from said transmission unit.

11. A charging-unit receiver as defined in claim 10, wherein the charging unit receiver is configured as a portable unit.

12. A charging-unit receiver as defined in claim 10; and further comprising an interface for establishing a connection with a data network.

13. A charging-unit receiver as defined in claim 12; and further comprising another interface configured for establishing a connection with a data network.

14. A charging-unit receiver as defined in claim 10; and further comprising an input device configured to allow an operator to input information.

15. A system, comprising a charging unit as defined in claim 1 and a charging-unit receiver as defined in claim 10.
